(19) United States
(12) Patent Application Publication
(10) Pub. No.: US 2025/0374803 A1
(43) Pub. Date: Dec. 4, 2025

(54) DISPLAY DEVICE INCLUDING COVER WINDOW

(71) Applicant: Samsung Display Co., LTD., Yongin-si (KR)

(72) Inventors: Seung Hwa HA, Yongin-si (KR); Jong-Seok CHAE, Yongin-si (KR)

(21) Appl. No.: 19/023,032

(22) Filed: Jan. 15, 2025

(30) Foreign Application Priority Data
May 28, 2024 (KR) 10-2024-0069575

(51) Int. Cl. H10K 59/80

(52) U.S. Cl. CPC H10K 59/873

(57) ABSTRACT

A display device includes: a display panel, and a cover window on the display panel, wherein the cover window includes a glass layer and a protective layer surrounding at least a part of the glass layer, and the protective layer includes a first part that overlaps the glass layer and a second part that does not overlap the glass layer, and the second part defines at least one edge of the cover window.

### CROSS-REFERENCE TO RELATED APPLICATION

The present application claims priority to and the benefit of Korean Patent Application No. 10-2024-0069575, filed on May 28, 2024, at the Korean Intellectual Property Office, the entire disclosure of which is incorporated herein by reference.

### BACKGROUND

### 1. Field

Aspects of some embodiments of the present disclosure relate to a display device and an electronic device including the cover window.

### 2. Description of the Related Art

Display devices such as organic light emitting displays and liquid crystal displays include display panels that are manufactured by forming multiple layers and elements on a substrate. Recently, flexible display panels and flexible display devices including them have been developed.

Flexible display devices may be classified into bendable display devices, foldable display devices, rollable display devices, and stretchable display devices, depending on their purpose or form. Among these, foldable display devices may be folded and unfolded like a book.

Foldable display devices may be able to be folded without being damaged and carried compactly and unfolded when in use to enjoy a wide screen.

The above information disclosed in this Background section is only for enhancement of understanding of the background and therefore the information discussed in this Background section does not necessarily constitute prior art.

### SUMMARY

A cover window used in a foldable display device may include thin glass to be folded, but the thin glass may be vulnerable to impact due to the thin thickness and the tapered structure of the outer part or edge of the glass.

Aspects of some embodiments of the present disclosure include a display device including a cover window that is resistant to impact and is relatively easy to manufacture.

A display device according to some embodiments includes a display panel, and a cover window on the display panel, wherein the cover window includes a glass layer and a protective layer surrounding at least a part of the glass layer, and the protective layer includes a first part that overlaps the glass layer and a second part that does not overlap the glass layer, and the second part define at least one edge of the cover window.

According to some embodiments, the cover window may further include a protective film on the glass layer, and the protective film may overlap the glass layer and the protective layer.

According to some embodiments, the display device may further include a first adhesive layer between the display panel and the glass layer, and a second adhesive layer between the glass layer and the protective layer.

According to some embodiments, the first part may include a first layer above the glass layer and a second layer below the glass layer, the thickness of the part of the first layer on the upper surface of the glass layer may be the same as the thickness of the second adhesive layer, and the thickness of the part of the second layer below the lower surface of the glass layer may be the same as the thickness of the first adhesive layer.

According to some embodiments, the first part may include the second layer below the glass layer, and the thickness of the part of the second layer below the lower surface of the glass layer may be the same as the thickness of the first adhesive layer, the second adhesive layer may be arranged over the entire area of the cover window.

According to some embodiments, the first part may include the first layer on the glass layer, the thickness of the part of the first layer on the upper surface of the glass layer may be the same as the thickness of the second adhesive layer, and the first adhesive layer may be arranged over the entire area of the cover window.

According to some embodiments, at least one of the first adhesive layer or the second adhesive layer may be a pressure-sensitive adhesive.

According to some embodiments, at least one of the first adhesive layer or the second adhesive layer may be an optically transparent resin.

According to some embodiments, the cover window may further include a light blocking layer between the protective film and the second adhesive layer.

According to some embodiments, the cover window may further include a coating layer on the upper and lower surface of the protective layer.

According to some embodiments, the display panel may include a pad part at one edge, and the protective layer may not be in an area where the cover window overlaps the pad part.

According to some embodiments, the cover window may include a folding part that may be folded along a first direction, and the protective layer may not be in the folding part.

A display device according to some embodiments includes a display panel and a cover window on the display panel, the cover window includes a glass layer and a protective layer that surrounds at least part of the glass layer, the protective layer includes a first part that overlaps the glass layer and a second part that does not overlap the glass layer, and the protective layer includes fiber-reinforced plastic.

According to some embodiments, the fiber-reinforced plastic may include a glass fiber layer and a resin layer.

According to some embodiments, the display panel may include a pad part at one edge, and the protective layer may not be in an area where the cover window overlaps the pad part.

According to some embodiments, the cover window may include a folding part that may be folded along a first direction, and the protective layer may not be in the folding part.

According to some embodiments, the resin layer may be filled in the glass fiber layer.

According to some embodiments, the cover window may further include a protective film, and the protective layer may overlap the glass layer and the protective layer.

According to some embodiments, the display device may further include a first adhesive layer on the upper part of the display panel, and a second adhesive layer below the protective layer.

According to some embodiments, the glass layer may have a tapered edge structure.

An electronic device according to some embodiments comprises a memory, a processor executing an application stored in the memory and a display device comprising a display module outputting video information provided by the application, wherein the display device comprises a display panel, and a cover window on the display panel, wherein the cover window includes a glass layer and a protective layer surrounding at least a part of the glass layer, and the protective layer includes a first part that overlaps the glass layer and a second part that does not overlap the glass layer, and the second part defines at least one edge of the cover window.

According to some embodiments, damage to the glass layer may be prevented or reduced by introducing a structure that protects the glass layer of the cover window, and process efficiency may be relatively increased by making it possible to manufacture it integrally with other materials. Additionally, various other characteristics of embodiments according to the present disclosure are illustrated and described below and would be apparent to a person having ordinary skill in the art based on the teachings of embodiments according to the present disclosure.

### BRIEF DESCRIPTION OF THE DRAWINGS

FIG. 1 is a schematic perspective view of an electronic device according to some embodiments.

FIG. 2 is a schematic perspective view of a display device including a cover window according to some embodiments.

FIG. 3 is a cross-sectional view of a display device according to some embodiments taken along the line A-A′ in FIG. 2.

FIG. 4 is a cross-sectional view of a display device according to some embodiments, taken along the line A-A′ in FIG. 2.

FIG. 5 is a cross-sectional view of an edge part of a cover window according to some embodiments.

FIG. 6A and FIG. 6B are schematic cross-sectional views showing a method of manufacturing a cover window according to some embodiments.

FIG. 7 is a cross-sectional view taken along the line A-A′ in FIG. 2.

FIG. 8 is a cross-sectional view of an edge part of a cover window according to some embodiments.

FIG. 9 is a cross-sectional view of a display device according to some embodiments taken along the line A-A′ in FIG. 2.

FIG. 10 is a cross-sectional view of an edge part of a cover window according to some embodiments.

FIGS. 11a, 11b, and 11c are schematic exploded perspective views of a cover window according to some embodiments.

FIG. 12 is an image of a cover window according to some embodiments.

FIG. 13 is a schematic cross-sectional view of a display panel according to some embodiments.

FIG. 14 is a block diagram of an electronic device according to some embodiments.

FIG. 15 shows schematic diagrams of electronic devices according to various embodiments

### DETAILED DESCRIPTION

Hereinafter, with reference to the attached drawings, various embodiments of the present disclosure will be described in detail so that those skilled in the art may easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to that which is shown. In the drawings, the thickness is enlarged to clearly express various layers and areas. And in the drawings, for convenience of explanation, the thicknesses of some layers and regions are exaggerated.

Additionally, when a part of a layer, membrane, region, or plate is said to be “above” or “on” another part, this includes not only cases where it is “directly above” another part, but also cases where there is another part in between. In contrast, when an element is referred to as being “directly on” another element, there are no intervening elements present. In addition, being “above” or “on” a reference part means being located above or below the reference part, and does not necessarily mean being located “above” or “on” it in the direction opposite to gravity.

In addition, throughout the specification, when a part is said to “include” a certain component, this means that it may further include other components rather than excluding other components, unless specifically stated to the contrary.

Throughout the specification, “connected” does not mean only the case where two or more components are directly connected, but also when two or more components are indirectly connected through other components, physically connected, or electrically connected, and it may include cases where each part, which is referred to by a different name depending on location or function but is substantially integrated, is connected to the others.

In the drawing, the symbols “DR1”, “DR2,” and “DR3” are used to indicate directions, where “DR1” represents the first direction, “DR2” represents the second direction which is perpendicular to the first direction, and “DR3” represents the third direction which is perpendicular to both the first and second directions.

In addition, throughout the specification, when reference is made to “on a plane,” this means when the target part is viewed from above, and when reference is made to “in a cross-section,” this means when a cross-section of the target part is cut vertically and viewed from the side.

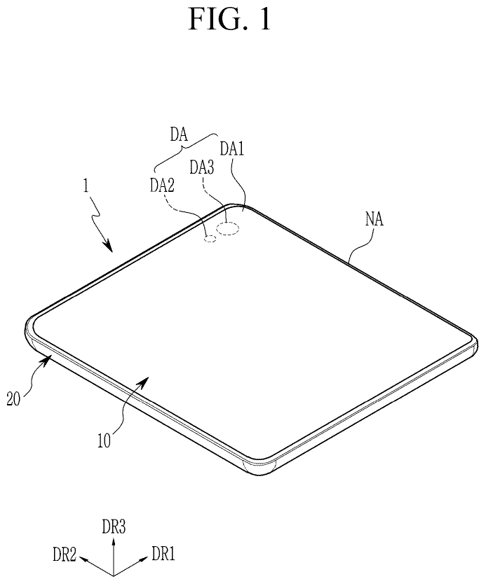

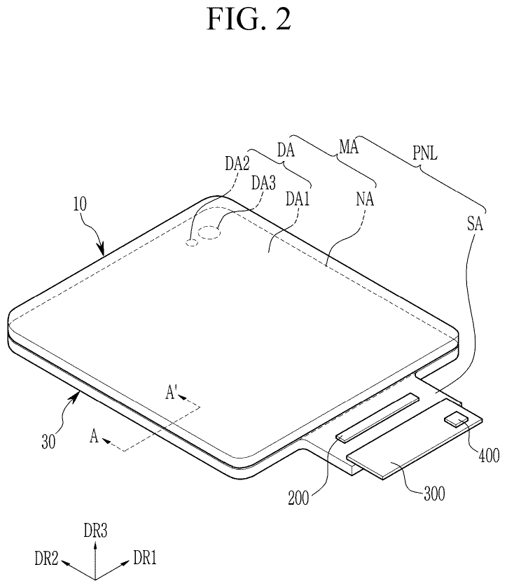

FIG. 1 is a schematic perspective view of an electronic device according to some embodiments, and FIG. 2 is a schematic perspective view of a display device including a cover window according to some embodiments.

Referring to FIGS. 1 and 2, the electronic device 1 may include a display screen capable of displaying images in a third direction DR3, which corresponds to the front in the plane defined by the first direction DR1 and the second direction DR2. For example, the electronic device 1 may include a television, laptop, monitor, billboard, mobile phone, smartphone, tablet, electronic watch, smart watch, watch phone, head mounted display (HMD), mobile communication terminal, electronic notebook, e-book, and the electronic device 1 may include a portable multimedia player PMP, navigation, game console, digital camera, camcorder, etc.

The electronic device 1 may include a housing 20, a display device 30 including a cover window 10, and the like.

The cover window 10 may include an insulating panel. For example, the cover window 10 may be made of glass, plastic, or a combination thereof. The front of the cover window 10 may define the front of the electronic device 1. An area of the cover window 10 corresponding to the display screen may be optically transparent. The cover window 10 is located above the display device 30 to protect the display device 30 from external shocks (e.g., dropping, external objects or impacts), etc., and to transmit images displayed by the display device 30. The cover window 10 may be bonded to the display device 30. The cover window 10 may be viewed as a part of the display device 30.

The housing 20 may be made of a material with relatively high rigidity. For example, the housing 20 may include a plurality of frames or plates made of glass, plastic, or metal, or a combination thereof. The housing 20 may be combined with the cover window 10, and the combined housing 20 and cover window 10 may form the exterior of the electronic device 1 and provide an internal space for the electronic device 1. For example, the housing 20 may form the back and sides of the electronic device 1, and the cover window 10 may form the front of the electronic device 1. The display panel PNL of the display device 30 may be located in the internal space limited by the cover window 10 and the housing 20, and the display panel PNL may be protected from the external environment.

The display device 30 may display an image and provide a display screen of the electronic device 1. The display device 30 may be a light emitting display device, such as an organic light emitting display device, an inorganic light emitting display device, or a quantum dot light emitting display device.

The electronic device 1 may have various shapes. For example, the electronic device 1 may have a rectangular shape with rounded corners when viewed from the front, as shown in FIG. 1. In addition, the electronic device 1 may have a shape such as a rectangle, square, polygon, circle, or oval.

The electronic device 1 and the display device 30 may include a display area DA and a non-display area NA, respectively. The display area DA and non-display area NA shown in FIG. 1 may correspond to the display area DA and non-display area NA of the display device 30 shown in FIG. 2. The display area DA is an area where images are displayed and may correspond to a display screen. The non-display area NA is an area where images are not displayed. The display area DA may occupy most of the area centered on the front of the electronic device 1, and the non-display area NA may surround (e.g., in a periphery or outside a footprint of) the display area DA.

The display area DA may include a first display area DA1, a second display area DA2, and a third display area DA3. The second display area DA2 and the third display area DA3 may be areas where components such as sensors and cameras for adding various functions to the electronic device 1 are placed on the rear side. The second display area DA2 and the third display area DA3 may correspond to a component area. The second display area DA2 and the third display area DA3 may be surrounded by the first display area DA1. In addition to the first display area DA1, the second display area DA2 and the third display area DA3 may all display images. The positions and numbers of the second display area DA2 and DA3 may be changed in various ways.

To describe the display device 30 in more detail, the display device 30 may provide a display screen in the electronic device 1. The display device 30 may detect or photograph the front of the electronic device 1. The display device 30 may have a planar shape similar to that of the electronic device 1.

The display device 30 may include a display panel PNL, a display driver 200, a printed circuit board 300, a touch driver 400, etc.

The display panel PNL may include a main area MA and a sub-area SA.

The main area MA may include a display area DA where pixels that display images are arranged, and a non-display area NA around the display area DA. The display area DA may include a first display area DA1, a second display area DA2, and a third display area DA3. Components such as sensors or cameras may be placed on the back of the second display area DA2 and DA3, and the second display area DA2 and third display area DA3 correspond to the component area.

The display area DA may emit light in the third direction DR3 from light-emitting areas corresponding to the light emitting elements. For example, the display panel 100 may include a pixel circuit part including transistors, signal lines (e.g., gate lines, data lines, and voltage lines) connected to the pixel circuit part, and a light emitting element connected to the pixel circuit part. The display panel 100 may include a pixel defining layer having an opening that defines a light emitting area of each light emitting device. The light emitting device may include an organic light emitting diode including an organic light emitting layer, a quantum dot light emitting diode including a quantum dot light emitting layer, an inorganic light emitting diode including an inorganic semiconductor, or a microlight emitting diode.

The non-display area NA may be defined as an edge area of the main area MA of the display panel 100. Circuits and/or signal lines for generating and/or transmitting various signals applied to the display area DA may be located in the non-display area NA. For example, in the non-display area NA, a gate driver that supplies gate signals to the gate lines and fan-out lines connecting the display driver 200 and signal lines in the display area DA are located.

The sub-area SA may be an area extending from one side of the main area MA. The sub-area SA may include a flexible area capable of bending, folding, rolling, etc. For example, the sub-area SA may be bent to overlap the main area MA in the thickness direction (third direction DR3). The display driver 200 may be located in the sub-area SA, and a pad area may be located at the edge. A printed circuit board 300 may be connected to the pad area. According to some embodiments, the sub-area SA may be omitted, and the display driver 200 and the pad area may be placed in the non-display area NA.

The display driver 200 may output signals and voltages for driving the display panel PNL. The display driver 200 may supply data voltages to data lines. The display driver 200 may supply power voltage to power lines and gate control signals to the gate driver. The display driver 200 may be formed as an integrated circuit chip and be mounted on the display panel PNL. For example, the display driver 200 may be located in the sub-area SA, and may overlap the main area MA in the thickness direction (third direction DR3) by bending the sub-area SA. According to some embodiments, the display driver 200 may be mounted on the printed circuit board 300.

The printed circuit board 300 may be bonded to the pad area of the display panel PNL using an anisotropic conductive film. Lead lines of the printed circuit board 300 may be electrically connected to pads in the pad area of the display panel PNL. The printed circuit board 300 may be flexible.

The touch driver 400 may be mounted on the printed circuit board 300. The touch driver 400 may be electrically connected to a touch sensor included in the electronic device 1. The touch sensor may be provided in the display area DA of the display panel PNL. The touch driver 400 may supply a touch driving signal to the sensing electrodes of the touch sensing unit and detect the amount of change in capacitance between the sensing electrodes. For example, the touch driving signal may be a pulse signal with a frequency (e.g., a set or predetermined frequency). The touch driver 400 may calculate whether a touch is touched and touch coordinates based on the amount of change in capacitance between the sensing electrodes. The touch driver 400 may be provided as an integrated circuit chip.

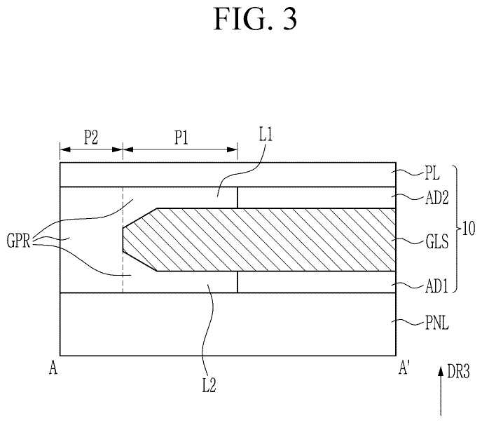

FIG. 3 is a cross-sectional view taken along the line A-A′ in FIG. 2 according to some embodiments.

Referring to FIG. 3, in the display device according to some embodiments, a cover window 10 may be located on one side of the display panel PNL. The cover window 10 is an optically transparent layer, and its surface may be exposed to the outside of the electronic device 1. The cover window 10 may serve to protect components located below it, particularly the display panel PNL.

The cover window 10 may include a glass layer GLS, a protective layer GPR, an adhesive layer AD1, AD2, and a protective film PL.

The glass layer GLS may be a glass film formed thin overall or locally. The glass layer GLS may have a tapered edge structure, and due to the edge structure of the glass layer GLS, it may be difficult to position the glass layer GLS at the outermost edge of the cover window 10.

The protective layer GPR may surround the glass layer GLS. The protective layer GPR may include a first part P1 that overlaps the glass layer GLS and a second part P2 that does not overlap the glass layer GLS. The second part P2 may define at least one edge of the cover window 10. The glass layer GLS may be vulnerable to impact due to its thin thickness and edge structure. Therefore, it may be difficult to locate the outermost part of the cover window 10. This can cause the adhesive, which is the material of the adhesive layers AD1, AD2, to flow from the top and bottom of the glass layer GLS, and can cause the protective film PL to be out of alignment with the periphery of the glass layer GLS, resulting in a risk of damage. Additionally, in the manufacturing process of the cover window 10, there may be restrictions on cutting it integrally with other materials. According to some embodiments, by including a protective layer GPR in the cover window 10, the risk of damage to the glass layer GLS may be minimized, and it may be possible to perform integrated cutting with other materials in the manufacturing process, allowing for relatively more efficient part production.

The protective layer GPR may include fiber-reinforced plastic FRP. Fiber-reinforced plastic may include a glass fiber layer GFB and a resin layer RES. Fiber-reinforced plastics are not limited to containing a glass fiber layer GFB and may have other fiber materials. The glass fiber layer GFB may include, but is not limited to, transparent glass fibers. The resin layer RES may include transparent resin, but is not limited thereto.

The first part P1 of the protective layer GPR may include a first layer L1 located above the glass layer GLS and a second layer L2 located below the glass layer GLS. The first layer L1 and the second layer L2 may include a resin layer RES and a glass fiber layer GFB. The resin layer RES located in the first layer L1 and the second layer L2 may include a part filled with the glass fiber layer GFB.

The first adhesive layer AD1 may be located between the display panel PNL and the glass layer GLS. The display panel PNL and the glass layer GLS may be attached by the first adhesive layer AD1.

The second adhesive layer AD2 may be located between the protective film PL and the glass layer GLS. The glass layer GLS and the protective film PL may be attached by the second adhesive layer AD2.

The adhesive layers AD1, AD2 may include pressure-sensitive adhesive PSA or optically clear resin OCR. The pressure-sensitive adhesive PSA may be in sheet form. Optically clear resin OCR may be formed by an inkjet process. When using an optically clear resin OCR for the adhesive layers AD1, AD2, the first layer L1 and the second layer L2 of the protective layer GPR may act as a dam, controlling the flow of the optically clear resin OCR. Therefore, this may facilitate the application of the optically clear resin OCR.

The protective film PL may be located on the glass layer GLS. The protective film PL may overlap the glass layer GLS and the protective layer GFB. The protective layer may include transparent synthetic resin. The protective film PL may include a hard coating layer.

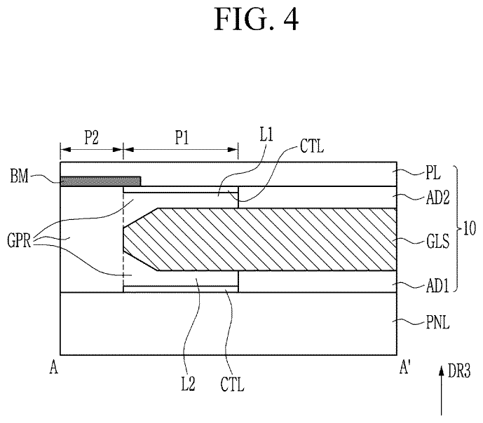

FIG. 4 is a cross-sectional view taken along the line A-A′ in FIG. 2 according to some embodiments.

The cover window 10 shown in FIG. 4 may further include a light blocking layer BM compared to the cover window 10 shown in FIG. 3. The light blocking layer BM may be located between the protective film PL and the second adhesive layer AD2. The light blocking layer BM may play a role in preventing or reducing scattering and leakage of light. In addition, a coating layer CTL may be further included on the upper and lower surfaces of the protective layer GPR. The coating layer CTL may be intended to improve the function of the protective layer GPR.

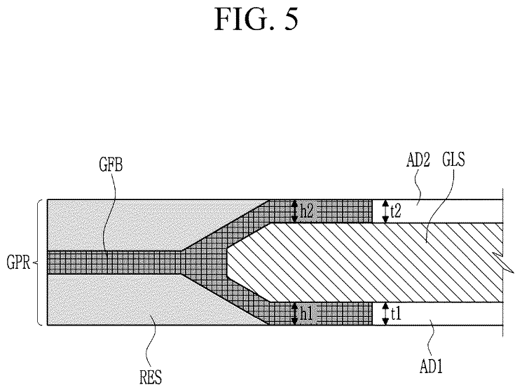

FIG. 5 is a cross-sectional view of an edge part of a cover window according to some embodiments.

According to some embodiments, the protective layer GPR of the cover window 10, as shown in FIG. 4, may include a first layer L1 located above the glass layer GLS and a second layer L2 located below the glass layer GLS.

The thickness h2 of the part of the first layer L1 located on the upper surface of the glass layer GLS may be equal to the thickness t2 of the second adhesive layer AD2. The first layer L1 may include a glass fiber layer GFB. The thickness of the glass fiber layer GFB included in the first layer L1 may be equal to the thickness t2 of the second adhesive layer AD2.

The thickness h1 of the part of the second layer L2 located below the lower surface of the glass layer GLS may be equal to the thickness t1 of the first adhesive layer AD1. The second layer L2 may include a glass fiber layer GFB. The thickness of the glass fiber layer GFB included in the second layer L2 may be the same as the thickness t1 of the first adhesive layer AD1. The thickness of the glass fiber layer GFB may be made the same as that of the adhesive layers AD1, AD2 so that there is no step between the protective layer GPR and the adhesive layers AD1, AD2.

The display device according to some embodiments may prevent or reduce damage to the glass layer GLS by introducing a protective layer GPR that protects the glass layer GLS. The protective layer GPR defines at least one edge of the cover window 10 and may be located at the outermost part of the cover window 10. Therefore, it may be possible to prevent or reduce damage to the outer edge of the glass layer GLS due to the leakage of the adhesives between the adhesive layers AD1, AD2 and the difference in level with the protective film PL, which occurs when the glass layer GLS is not located at the outermost part. In the case of the existing structure, the protective film PL and the adhesive layers (AD1, AD2) are laminated and then punched out, and after the punching process, the glass layer GLS may be laminated. When introducing the protective layer GPR, immediately after forming the protective layer GPR, it may be possible to laminate in sequence with the adhesive layers AD1, AD2 and the protective film PL, and after all layers are laminated, laser cutting may be performed to manufacture the cover window 10 at once. Because the cover window 10 may be manufactured at once, the process may be simplified. In addition, the cover window 10 may be managed as a whole without separately managing the constituent materials of the cover window 10, which may be efficient in terms of parts management.

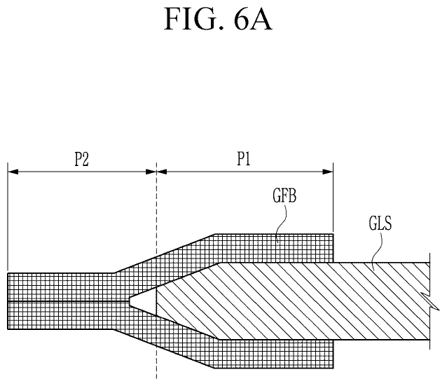

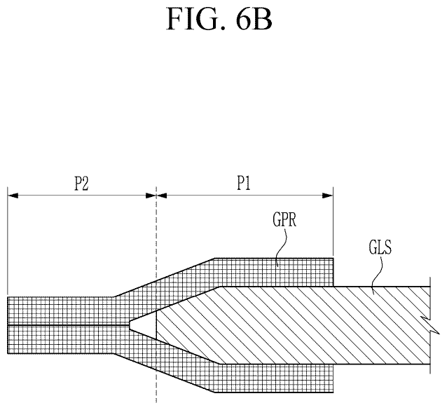

FIG. 6A and FIG. 6B are schematic cross-sectional views showing a method of manufacturing a cover window according to some embodiments.

As shown in FIG. 6A, the protective layer GPR may include a first part P1 that overlaps the glass layer GLS and a second part P2 that does not overlap the glass layer. Sheet-shaped glass fibers may be laminated with a glass layer GLS in the first part P1 using heat and pressure, and materials of the same type may be laminated in the second part P2 to form a glass fiber layer GFB. Thereafter, as shown in FIG. 6B, resin may be applied to the glass fiber layer GFB to form a resin layer RES. The resin layer RES may be filled in the glass fiber layer GFB. The protective layer GPR may include a region where the glass fiber layer GFB and the resin layer RES exist simultaneously, and a region where the resin layer RES exists alone.

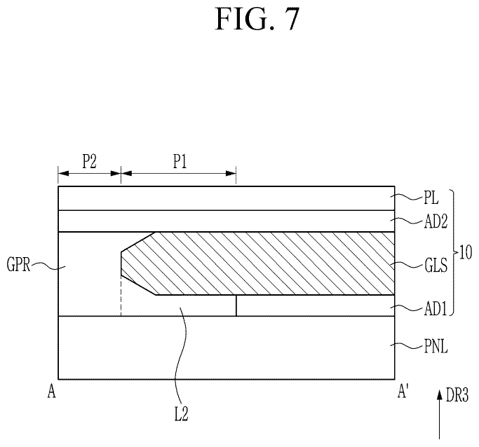

FIG. 7 is a cross-sectional view taken along the line A-A′ in FIG. 2.

Referring to FIG. 7, in the display device according to some embodiments, the cover window 10 may be located on one side of the display panel PNL. The cover window 10 may include a glass layer GLS, a protective layer GPR, an adhesive layer AD1, AD2, and a protective film PL.

The protective layer GPR may surround the glass layer GLS. The protective layer GPR may include the first part P1 that overlaps the glass layer GLS and the second part P2 that does not overlap the glass layer GLS. The second part P2 may define at least one edge of the cover window 10.

In the display device according to some embodiments, the first part P1 of the protective layer GPR may include a second layer L2 located below the glass layer GLS. The second layer L2 may include the resin layer RES and the glass fiber layer GFB. The resin layer RES located in the second layer L2 may include a part filled with the glass fiber layer GFB.

The first adhesive layer AD1 may be located between the display panel PNL and the glass layer GLS. The display panel PNL and the glass layer GLS may be attached by the first adhesive layer AD1.

The second adhesive layer AD2 may be located between the protective film PL and the glass layer GLS. The second adhesive layer AD2 may be located over the entire area of the cover window 10. The glass layer GLS and the protective film PL may be attached by the second adhesive layer AD2.

According to some embodiments, the display device uses the optically clear resin OCR as the adhesive layer AD1, AD2, and the second layer L2 of the protective layer GPR may act as a dam to control the flowability of the optically clear resin OCR. Therefore, this may facilitate the application of the optically clear resin OCR.

The protective film PL may be located on the glass layer GLS. The protective film PL may overlap the glass layer GLS and the protective layer GPR.

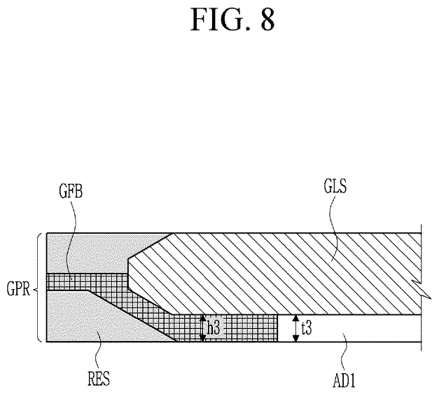

FIG. 8 is a cross-sectional view of an edge part of a cover window according to some embodiments.

A display device according to some embodiments may include a second layer L2 located below the glass layer GLS, as shown in FIG. 6.

The thickness h3 of the part of the second layer L2 located below the lower surface of the glass layer GLS may be equal to the thickness t3 of the first adhesive layer AD1. The second layer L2 may include a glass fiber layer GFB. The thickness of the glass fiber layer GFB included in the second layer L2 may be the same as the thickness t3 of the first adhesive layer AD1.

The display device according to some embodiments may prevent or reduce damage to the glass layer GLS, as shown in FIG. 3, simplifying the manufacturing process, and enabling efficient parts management.

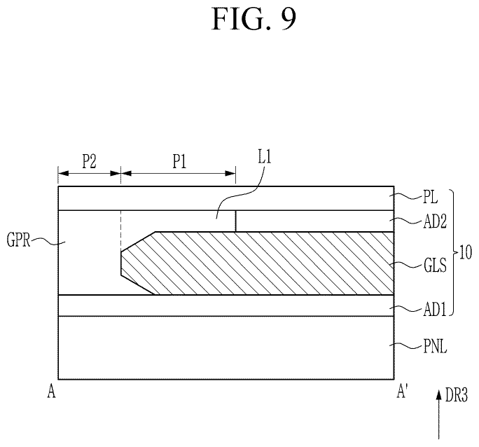

FIG. 9 is a cross-sectional view of a display device according to some embodiments taken along the line A-A′ in FIG. 2.

Referring to FIG. 9, the display device according to some embodiments may have a cover window 10 located on one side of the display panel PNL. The cover window 10 may include a glass layer GLS, a protective layer GPR, adhesive layers AD1, AD2, and a protective film PL.

The protective layer GPR may surround the glass layer GLS. The protective layer GPR may include a first part P1 that overlaps the glass layer GLS and a second part P2 that does not overlap the glass layer GLS. The second part P2 may define at least one edge of the cover window 10.

In the display device according to some embodiments, the first part P1 of the protective layer GPR may include a first layer L1 located on the glass layer GLS. The first layer L1 may include a resin layer RES and a glass fiber layer GFB. The resin layer RES located in the first layer L1 may include a part filled with the glass fiber layer GFB.

The first adhesive layer AD1 may be located between the display panel PNL and the glass layer GLS. The display panel PNL and the glass layer GLS may be attached by the first adhesive layer AD1. The first adhesive layer AD1 may be located over the entire area of the cover window 10.

The second adhesive layer AD2 may be located between the protective film PL and the glass layer GLS.

In the display device according to some embodiments, when the optically transparent resin OCR is used as the adhesive layers AD1, AD2, the first layer L1 of the protective layer acts as a dam to control the flow of the optically transparent resin OCR. Therefore, this may facilitate the application of the optically clear resin OCR.

The protective film PL may be located on the glass layer GLS. The protective film PL may overlap the glass layer GLS and the protective layer GPR.

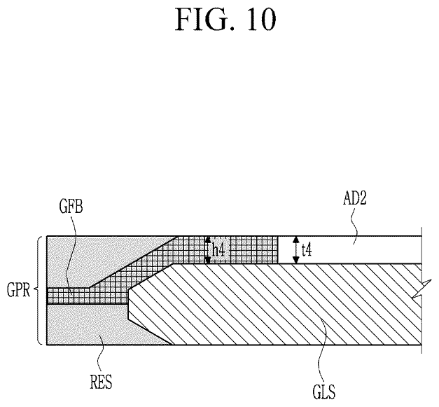

FIG. 10 is a cross-sectional view of an edge part of a cover window according to some embodiments.

A display device according to some embodiments may include a first layer L1 located on the glass layer GLS, as shown in FIG. 8.

The thickness h4 of the part of the first layer L1 located on the upper surface of the glass layer GLS may be equal to the thickness t4 of the second adhesive layer AD2. The first layer L1 may include a glass fiber layer GFB. The thickness of the glass fiber layer GFB included in the first layer L1 may be equal to the thickness t4 of the second adhesive layer AD2.

The display device according to some embodiments may prevent or reduce damage to the glass layer GLS, simplifying the manufacturing process, and enabling efficient parts management, as shown in FIG. 3.

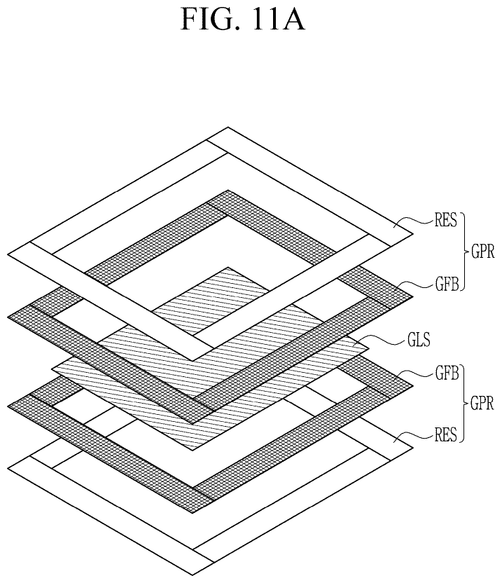

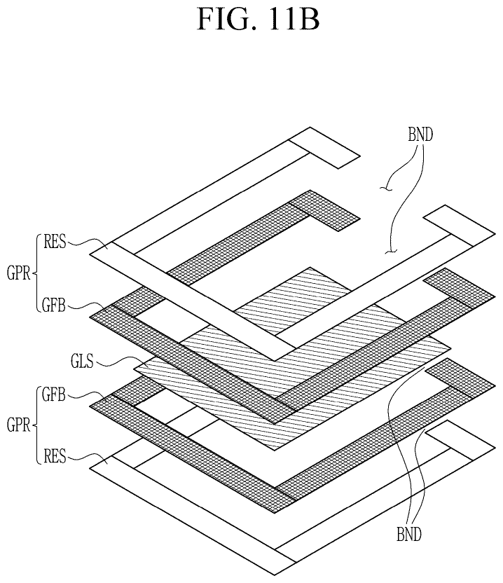

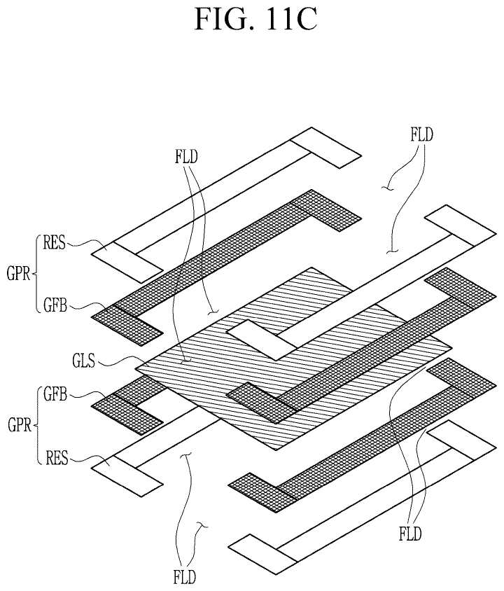

FIGS. 11a, 11b, and 11c are schematic exploded perspective views of a cover window according to some embodiments.

Referring to FIG. 11a, in a cover window 10 according to some embodiments, the glass layer GLS may have an approximately rectangular planar shape, and the protective layer GPR may surround all four sides of the glass layer GLS.

Referring to FIG. 11b, in the cover window according to some embodiments, there may be an area where the protective layer GPR is not located. The pad part may be located at one edge of the display panel PNL, and the protective layer GPR may not be located in an area where the cover window 10 overlaps the pad part. This may serve to prevent or reduce instances of the printed circuit board connected to the pad part of the display panel PNL interfering with the protective layer GPR.

Referring to FIG. 11C, in the cover window according to some embodiments, there may be an area where the protective layer GPR is not located. The cover window 10 may include a folding part FLD that may be folded along the first direction. The cover window 10 is a flexible window that may be folded at least in part. The cover window 10 may be flexible in the folding part FLD and may be flexible overall. The protective layer GPR may not be adjacent to the folding part FLD. This may be a structure in consideration of folding the display device.

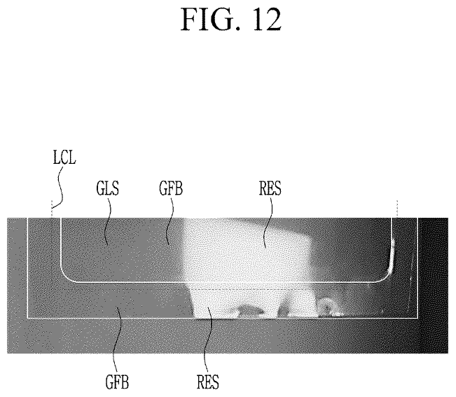

FIG. 12 is an image of an example of a real object according to some embodiments.

FIG. 12 is an image taken from top to bottom with a protective material layer bonded to the glass layer GLS. The protective material layer may include a glass fiber layer GFB and a resin layer RES. Looking at the state in which the glass layer GLS and the protective material layer are bonded, there may be a part where the protective material layer and the glass layer GLS overlap and a part where the protective material layer exists alone. Afterwards, the protective material layer is cut along the cutting line LCL to form a protective layer GPR, and a part may be made in which the protective layer GPR and glass layer GLS are bonded. Afterwards, by bonding adhesive layers AD1, AD2 or applying the optically transparent resin OCR through an inkjet process, it may be possible to create a component in which the protective layer GPR, glass layer GLS, and adhesive layers AD1, AD2 are bonded together.

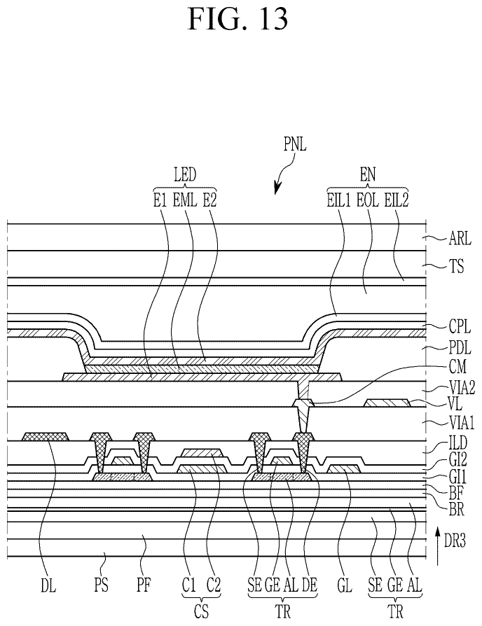

FIG. 13 is a schematic cross-sectional view of a display panel according to some embodiments.

Referring to FIG. 13, the illustrated cross-section may correspond to approximately one pixel area. The display panel PNL basically includes substrate SB, a transistor TR formed on the substrate SB, and a light emitting diode LED connected to the transistor TR. The light emitting diode LED may correspond to a pixel.

The substrate SB may be a flexible substrate capable of bending, folding, rolling, etc. The substrate SB may have a multi-layer structure including a first base layer BL1, an inorganic layer IL, and a second base layer BL2. The first base layer BL1 and the second base layer BL2 may include a polymer resin such as polyimide, polyamide, or polyethylene terephthalate. A barrier layer BR may be located on the substrate SB to prevent or reduce instances of contaminants such as moisture, oxygen, etc., penetrating. The barrier layer BR may include an inorganic insulating material such as silicon nitride SiNx, silicon oxide SiOx, or silicon nitride SiOxNy, and may have a single layer or multiple layers.

A buffer layer (BF) may be located on the barrier layer BR. The buffer layer BF may improve the characteristics of the semiconductor layer by blocking impurities from the substrate SB when forming the semiconductor layer, and may relieve stress of the semiconductor layer by flattening the surface of the substrate SB. The buffer layer BF may include an inorganic insulating material such as silicon nitride, silicon oxide, or silicon nitride, and may have a single layer or multiple layers. The buffer layer BF may include amorphous silicon a-Si.

The semiconductor layer AL of the transistor TR may be located on the buffer layer BF. The semiconductor layer AL may include a first region, a second region, and a channel region between these regions. The semiconductor layer AL may include any one of amorphous silicon, polycrystalline silicon, and oxide semiconductor. The oxide semiconductor may include at least one of zinc (Zn), indium (In), gallium (Ga), or tin (Sn). For example, the semiconductor layer AL may include low-temperature polycrystalline silicon LTPS or indium-gallium-zinc oxide IGZO.

A first gate insulating layer GI1 may be located on the semiconductor layer AL. The first gate insulating layer GI1 may include an inorganic insulating material such as silicon nitride, silicon oxide, or silicon nitride, and may have a single-layer or a multilayer structure.

Above the first gate insulating layer GI1, there may be located a first gate conductive layer that may include the gate electrode GE of the transistor TR, the gate line GL, and the first electrode C1 of the storage capacitor CS. The first gate conductive layer may include molybdenum (Mo), aluminum (AI), copper (Cu), titanium (Ti), etc., and may have a single layer or multiple layers.

A second gate insulating layer GI2 may be located on the first gate conductive layer. The second gate insulating layer GI2 may include an inorganic insulating material such as silicon nitride, silicon oxide, or silicon nitride, and may have a single-layer or a multilayer structure.

A second gate conductive layer that may include the second electrode C2 of the storage capacitor CS may be located on the second gate insulating layer GI2. The second gate conductive layer may include molybdenum (Mo), aluminum (AI), copper (Cu), titanium (Ti), etc., and may have a single-layer or a multilayer structure.

An interlayer insulating layer ILD may be located on the second gate insulating layer GI2 and the second gate conductive layer. The interlayer insulating layer ILD may include an inorganic insulating material such as silicon nitride, silicon oxide, or silicon nitride, and may have a single layer or multiple layers.

A first data conductive layer that may include the first electrode SE and second electrode DE of the transistor TR, the data line DL, etc. may be located on the interlayer insulating layer ILD. The first electrode SE and the second electrode DE may be connected to the first and second regions, respectively, of the semiconductor layer AL through contact holes of the insulating layers Gl1, GI2, and ILD. One of the first electrode SE and the second electrode DE may be a source electrode and the other may be a drain electrode. The first data conductive layer is aluminum (Al), platinum (Pt), palladium (Pd), silver (Ag), magnesium (Mg), gold (Au), nickel (Ni), neodymium (Nd), and iridium (Ir), chromium (Cr), calcium (Ca), molybdenum (Mo), titanium (Ti), tungsten (W), copper (Cu), etc., and may have a single layer or multiple layers.

A first planarization layer VIA1 may be located on the first data conductive layer. The first planarization layer VIA1 may include organic insulating materials such as general-purpose polymers like polymethyl methacrylate, polystyrene, polymer derivatives containing phenolic groups, acrylic polymers, imide polymers (for example, polyimide), and siloxane polymers.

A second data conductive layer that may include a power line VL, a connection member CM, etc. may be located on the first planarization layer VIA1. The power line VL may transmit voltages such as driving voltage, common voltage, initialization voltage, and reference voltage. The connection member CM may be connected to the second electrode DE of the transistor TR through a contact hole in the first planarization layer VIA1. The second data conductive layer is aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), etc., and may have a single layer or multiple layers.

A second planarization layer VIA2 may be located on the second data conductive layer. The second planarization layer VIA2 may include an organic insulating material such as a general-purpose polymer such as polymethyl methacrylate or polystyrene, a polymer derivative having a phenolic group, an acrylic polymer, an imide polymer, or a siloxane polymer.

The first electrode E1 of the light emitting diode LED may be located on the second planarization layer VIA2. The first electrode E1 may be called a pixel electrode. The first electrode E1 may be connected to the connection member CM through a contact hole in the second planarization layer VIA2. Accordingly, the first electrode E1 is electrically connected to the second electrode DE of the transistor TR and may receive a driving current that controls the brightness of the light emitting diode. The transistor TR to which the first electrode E1 is connected may be a driving transistor or a transistor electrically connected to the driving transistor. The first electrode E1 may be formed of a reflective conductive material or a semi-transparent conductive material, or may be formed of a transparent conductive material. The first electrode E1 may include a transparent conductive material such as indium tin oxide ITO or indium zinc oxide IZO. The first electrode E1 may include lithium (Li), calcium (Ca), aluminum (AI), silver (Ag), magnesium (Mg), gold (Au), etc.

A pixel defining layer PDL may be located on the second planarization layer VIA2 and the first electrode E1. The pixel defining layer PDL may be called a bank or a partition, and may have an opening that overlaps the first electrode E1. The pixel defining layer PDL may include organic insulating materials such as general-purpose polymers like polymethyl methacrylate and polystyrene, polymer derivatives with phenolic groups, acrylic polymers, imide polymers, and siloxane polymers.

The light emitting layer EL of the light emitting diode LED may be located on the first electrode E1. In addition to the light emitting layer EL, a functional layer including at least one of a hole injection layer, a hole transport layer, an electron transport layer, or an electron injection layer may be located on the first electrode E1.

The second electrode E2 of the light emitting diode LED may be located on the light emitting layer EL. The second electrode E2 may be called a common electrode. The second electrode E2 may be made to have light transmissibility by forming a thin layer of metals or metal alloys with low work functions such as calcium (Ca), barium (Ba), magnesium (Mg), aluminum (AI), silver (Ag), etc. The second electrode E2 may include a transparent conductive oxide such as indium tin oxide ITO or indium zinc oxide IZO.

The first electrode E1, the light emitting layer EL, and the second electrode E2 of each pixel may form a light emitting diode LED such as an organic light emitting diode. The first electrode E1 may be an anode, and the second electrode E2 may be a cathode. The light emitting area of a light emitting diode LED may correspond to a pixel.

A capping layer CPL may be located on the second electrode E2. The capping layer CPL may improve light efficiency by adjusting the refractive index. The capping layer CPL may be arranged to entirely cover the second electrode E2. The capping layer CPL may include an organic insulating material or an inorganic insulating material.

An encapsulation layer EN may be located on the capping layer CPL. The encapsulation layer EN may seal the light emitting diode LED and prevent or reduce instances of contaminants such as moisture or oxygen penetrating from the outside.

The encapsulation layer EN may be a thin-film encapsulation layer in which the organic layer EOL is located between the first inorganic layer EIL1 and the second inorganic layer EIL2.

A touch sensor layer TS including touch electrodes may be located on the encapsulation layer EN. A reflection reduction layer ARL may be located on the touch sensor layer TS to reduce external light reflection.

A protective layer PF may be located under the substrate SB. The protective layer PF may protect the display panel PNL during the manufacturing process of the display device. The protective layer PF may include a polymer such as polyethylene terephthalate, a silicone-based polymer (e.g., polydimethylsiloxane), or an elastomer (e.g., elastomeric polyurethane).

A protective sheet PS may be located below the protective layer PF.

A display device according to an embodiment may be applied to various electronic devices. An electronic device according to an embodiment may include the display device, and may further include modules or devices having additional functions other than the display device.

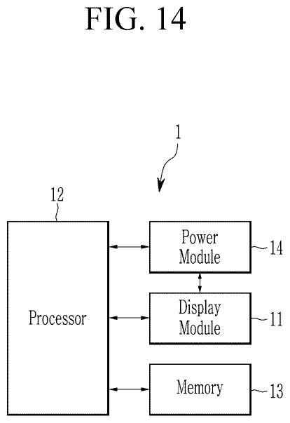

FIG. 14 is a block diagram of an electronic device according to some embodiments. Referring to FIG. 14, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 1.

At least one of components of the electronic device 1 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 1 that are not part of the display device.

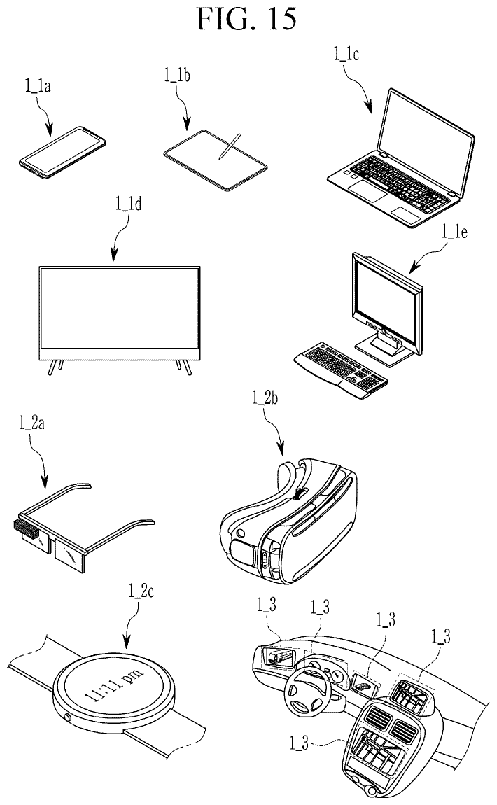

FIG. 15 shows schematic diagrams of electronic devices according to various embodiments.

Referring to FIG. 15, various electronic devices with the display device according to the embodiments may include not only image display electronic devices such as smartphones 1_1a, tablet PCs 1_1b, laptops 1_1c, TVs 1_1d, desktop monitors 1_1e, but also wearable electronic devices with display modules such as smart glasses 1_2a, head-mounted displays 1_2b, smart watches 1_2c, as well as automotive electronic devices with display modules 1_3 such as those placed on car dashboards, center fascias, CID (Center Information Display), room mirror displays, and so on.

Although aspects of some embodiments of the present disclosure have been described in detail above, the scope of embodiments according to the present disclosure are not limited thereto, and various modifications and improvements made by those skilled in the art using the basic concepts of the present disclosure defined in the following claims, and their equivalents, are also possible.

### DESCRIPTION OF SOME OF THE REFERENCE SYMBOLS

1: electronic device
10: cover window
20: housing
30: display device
PNL: display panel
AD: adhesive layer
GLS: glass layer
GPR: protective layer
PL: protective film
P1: first part
P2: second part
L1: first layer
L2: second layer
RES: resin layer
GFB: glass fiber layer
FLD: folding part
LCL: cutting line

what is claimed is:

1. A display device, comprising:
a display panel, and
a cover window on the display panel,
wherein the cover window includes a glass layer and a protective layer surrounding at least a part of the glass layer, and
the protective layer includes a first part that overlaps the glass layer and a second part that does not overlap the glass layer, and the second part defines at least one edge of the cover window.

2. The display device of claim 1, wherein:
the cover window further includes a protective film on the glass layer, and
the protective film overlaps the glass layer and the protective layer.

3. The display device of claim 2, further comprising:
a first adhesive layer between the display panel and the glass layer; and
a second adhesive layer between the glass layer and the protective layer.

4. The display device of claim 3, wherein:
the first part includes a first layer above the glass layer and a second layer below the glass layer,
a thickness of the part of the first layer on an upper surface of the glass layer is equal to a thickness of the second adhesive layer, and
a thickness of the part of the second layer below a lower surface of the glass layer is equal to a thickness of the first adhesive layer.

5. The display device of claim 4, wherein:
the first part includes the second layer below the glass layer,
a thickness of the part of the second layer below a lower surface of the glass layer is equal to a thickness of the first adhesive layer, and
the second adhesive layer is over an entire area of the cover window.

6. The display device of claim 4, wherein:
the first part includes the first layer on the glass layer,
a thickness of the part of the first layer on an upper surface of the glass layer is equal to a thickness of the second adhesive layer, and
the first adhesive layer is over an entire area of the cover window.

7. The display device of claim 3, wherein:
at least one of the first adhesive layer or the second adhesive layer is a pressure-sensitive adhesive.

8. The display device of claim 3, wherein:
at least one of the first adhesive layer or the second adhesive layer is an optically transparent resin.

9. The display device of claim 3, wherein:
the cover window further includes a light blocking layer between the protective film and the second adhesive layer.

10. The display device of claim 3, wherein:
the cover window further includes a coating layer on an upper and lower surface of the protective layer.

11. The display device of claim 1, wherein:
the display panel includes a pad part at one edge, and
the protective layer is not in an area where the cover window overlaps the pad part.

12. The display device of claim 1, wherein:
the cover window includes a folding part that may be folded along a first direction, and
the protective layer is not in the folding part.

13. A display device, comprising:
a display panel, and
a cover window on the display panel,
wherein the cover window includes a glass layer and a protective layer surrounding at least a part of the glass layer,
the protective layer includes a first part that overlaps the glass layer and a second part that does not overlap the glass layer, and
the protective layer includes fiber-reinforced plastic.

14. The display device of claim 13, wherein:
the fiber-reinforced plastic includes a glass fiber layer and a resin layer.

15. The display device of claim 14, wherein:
the display panel includes a pad part at one edge, and
the protective layer is not in an area where the cover window overlaps the pad part.

16. The display device of claim 14, wherein:
the cover window includes a folding part that may be folded along a first direction, and
the protective layer is not in the folding part.

17. The display device of claim 14, wherein:
the resin layer is filled in the glass fiber layer.

18. The display device of claim 14, wherein:
the cover window further includes a protective film, and
the protective film overlaps the glass layer and the protective layer.

19. The display device of claim 18, further comprising:
a first adhesive layer on an upper part of the display panel; and
a second adhesive layer below the protective layer.

20. The display device of claim 13, wherein:
the glass layer has a tapered edge.

21. An electronic device comprising:
a memory;
a processor executing an application stored in the memory; and
a display device comprising a display module outputting video information provided by the application, wherein
the display device comprising:
a display panel, and
a cover window on the display panel,
wherein the cover window includes a glass layer and a protective layer surrounding at least a part of the glass layer, and
the protective layer includes a first part that overlaps the glass layer and a second part that does not overlap the glass layer, and the second part defines at least one edge of the cover window.
